(19) United States
(12) Patent Application Publication
(10) Pub. No.: US 2025/0062663 A1
(43) Pub. Date: Feb. 20, 2025

(54) POWER TOOL USER INTERFACE PRINTED CIRCUIT BOARD

(71) Applicant: MILWAUKEE ELECTRIC TOOL CORPORATION, Brookfield, WI (US)

(72) Inventors: Alejandro M. Damonte Vegas, Glendale, WI (US); William Z. Weis, Richfield, WI (US)

(21) Appl. No.: 18/806,012

(22) Filed: Aug. 15, 2024

Related U.S. Application Data
(60) Provisional application No. 63/520,503, filed on Aug. 18, 2023.
(60) Provisional application No. 63/671,317, filed on Jul. 15, 2024.

(51) Int. Cl. H02K 11/28; B25F 5/02; G01D 5/14; G01D 5/20; H02K 7/14

(52) U.S. Cl. CPC H02K 11/28; B25F 5/02; H02K 7/145; G01D 5/145; G01D 5/202; H02K 2211/03

(57) ABSTRACT

A power tool includes a housing, a motor at least partially disposed in the housing, a controller configured to control an operational characteristic of the motor, and a circuit board. The circuit board is connected to the controller. The circuit board includes a first sensor portion configured to sense a first position of a first user input device, a second sensor configured to sense a second position of a second user input device, and a third sensor configured to sense a third position of a third user input device.

### RELATED APPLICATIONS

This application claims the benefit of U.S. provisional patent application No. 63/520,503, filed Aug. 18, 2023, and U.S. Provisional patent application No. 63/671,317, filed Jul. 15, 2024, the entire content of each of which is hereby incorporated by reference.

### FIELD

This disclosure relates to a power tool.

### SUMMARY

A power tool may include an electric motor, a controller, and a circuit board including a sensor. The controller may be configured to set the operational characteristics of the electric motor. For example, the controller may be configured to set the torque output by the electric motor, the direction of rotation, or the rotational speed of the electric motor. The controller may be configured to determine a position of one or more user input devices of the power tool such as triggers, dials, sliders, switches (e.g., multi-position switches), knobs, etc., based on signals from the sensor, and the controller may be configured to set an operational characteristic of the motor based on the determined position or the sensor data.

Embodiments described herein may provide a power tool including a housing, a motor at least partially disposed in the housing, a controller configured to control an operational characteristic of the motor, and a circuit board. The circuit board is connected to the controller. The circuit board includes a first sensor portion configured to sense a first position of a first user input device, a second sensor configured to sense a second position of a second user input device, and a third sensor configured to sense a third position of a third user input device.

Embodiments described herein may provide a power tool including a housing, a motor at least partially disposed within the housing, a controller configured to control an operational characteristic of the motor in response to receiving a wake signal, and a circuit board connected to the controller. The circuit board includes a first sensor configured to sense a first position of a first user input device and a second sensor configured to sense a second position of the first user input device.

Embodiments described herein may provide a trigger switch. The trigger switch includes a trigger including a target portion. The trigger is actuatable by a user to move the target portion from a first position to a second position. A printed circuit board (PCB) has a first non-contact sensor and a second non-contact sensor. The PCB is disposed above the trigger such that the trigger moves between the first position and the second position along a bottom side of the PCB. The first non-contact sensor is configured to detect a position of the target portion as the target portion moves between the first position and the second position. The second non-contact sensor is configured to provide a wake signal to a controller in response to the target portion being moved from the first position.

Before any embodiments are explained in detail, it is to be understood that the embodiments are not limited in application to the details of the configurations and arrangements of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other features and aspects of the disclosure will become apparent by consideration of the following detailed description and accompanying drawings.

### BRIEF DESCRIPTION OF THE DRAWINGS

FIG. 1 is a perspective view of a power tool including a dial adjustment interface according to various embodiments described herein.

FIG. 2 is an enlarged side view of the power tool of FIG. 1.

FIG. 3 shows a circuit board disposed in the power tool of FIG. 1.

FIG. 4 shows another view of the circuit board disposed in the power tool of FIG. 1.

FIGS. 5A and 5B show user input devices in proximity to the circuit board.

FIG. 6 illustrates a block diagram of a controller for the power tool of FIG. 1 in accordance with various embodiments described herein.

FIG. 7 shows a top and bottom of view of a circuit board for the power tool of FIG. 1 in accordance with various embodiments described herein.

FIG. 8 shows a top and bottom of view of a circuit board for the power tool of FIG. 1 in accordance with various embodiments described herein.

FIG. 9 shows a sensing portion of a circuit board including interweaved inductive traces.

FIGS. 10A and 10B show a side and perspective view of a trigger of the power tool of FIG. 1 according to various embodiments described herein.

FIGS. 11A, 11B, and 11C illustrate a spring and a sensor for detecting the compression of the spring according to various embodiments described herein.

FIG. 11D is a graph of coil density versus length for the spring of FIGS. 11A, 11B, and 11C.

FIGS. 12A, 12B, and 12C illustrate a spring and a sensor for detecting the compression of the spring according to various embodiments described herein.

FIGS. 13A, 13B, and 13C illustrate a spring and a plurality of sensors for detecting the compression of the spring according to various embodiments described herein.

FIGS. 14A, 14B, and 14C illustrate a spring including a conductive member and a sensor for detecting the compression of the spring according to various embodiments described herein.

FIGS. 15A, 15B, and 15C illustrate a spring including a conductive member and a sensor for detecting the compression of the spring according to various embodiments described herein.

FIG. 16 shows a dial of a power tool according to various embodiments described herein.

FIG. 17 shows a circular sensing portion of a circuit board including interweaved inductive traces.

FIG. 18 illustrates the output of an inductive sensor as the target portion of FIG. 16 moves over the interweaved inductive traces of the circular sensing portion of FIG. 17.

FIG. 19 shows a circular sensing portion of a circuit board including layered inductive traces.

FIG. 20 shows a flow chart for a method of receiving and processing signals from sensors on a control board to control an operational characteristic of a motor of the power tool of FIG. 1.

FIGS. 21A, 21B, and 21C illustrate a circuit board including a plurality of sensing portions and sensing components according to various embodiments described herein.

FIG. 22 shows a flow chart for a method of receiving and processing signals from sensors on the circuit board of FIGS. 21A, 21B, and 21C and controlling an operational characteristic of a power tool based on the sensor signals.

### DETAILED DESCRIPTION

Modern power tools may include an electric motor, a controller, and various sensors configured to communicate with the controller. The sensors of the power tool may be distributed throughout the power tool and may each have associated circuit boards with which the sensors are configured to communicate.

The disclosed power tools include a centrally-located circuit board that accommodates multiple sensors. The multiple sensors are configured to sense the positions of multiple user input devices simultaneously.

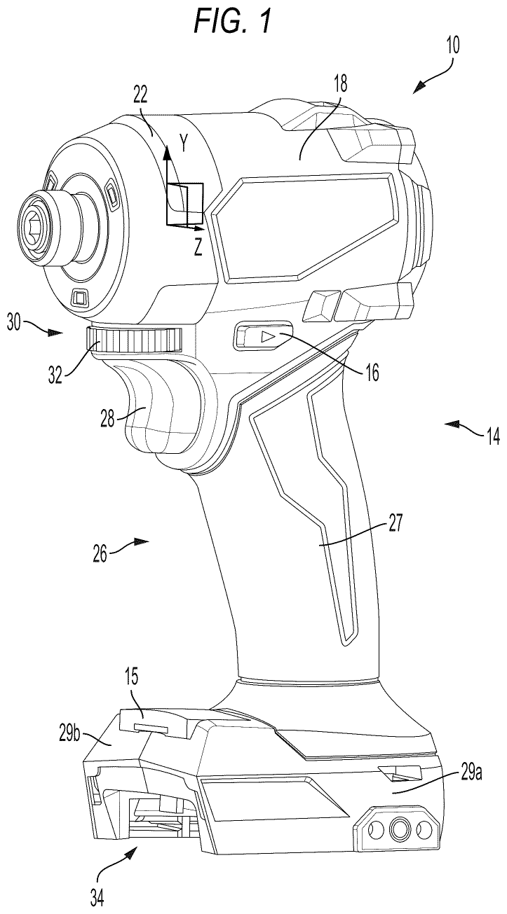

FIG. 1 illustrates a power tool 10 in the form of a rotary impact tool (e.g., an impact driver). The illustrated power tool 10 includes a housing 14 with a motor housing portion 18 enclosing a motor (e.g., a brushless DC motor), a front housing portion or case 22 coupled to the motor housing portion 18 (e.g., by a plurality of fasteners), and a handle portion 26 extending downwardly from the motor housing portion 18. The handle portion 26 includes a grip 27 that can be grasped by a user. A trigger 28 is coupled to a front side of the handle portion 26 and can be actuated by the user to operate the power tool 10. In the illustrated embodiment, the handle portion 26 and the motor housing portion 18 are defined by cooperating clamshell halves 29a, 29b.

The power tool 10 has a battery pack receptacle 34 located at a bottom end of the handle portion 26. The battery pack receptacle 34 is configured to receive a battery pack (not shown), which provides power to the motor. In other embodiments, the power tool 10 may include a power cord for electrically connecting the power tool 10 to a source of AC power. As a further alternative, the power tool 10 may be configured to operate using a different power source (e.g., a pneumatic power source, etc.).

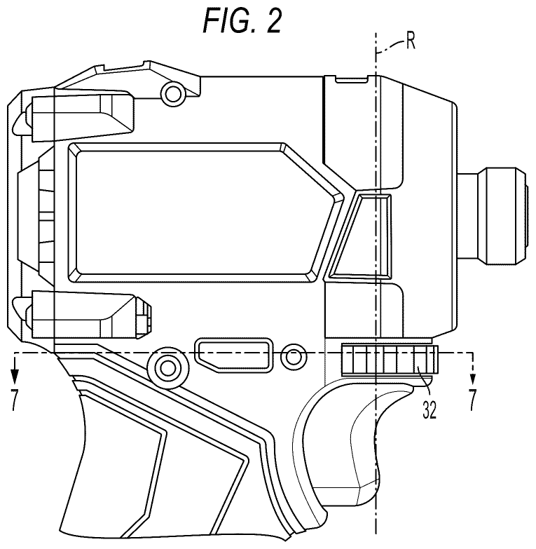

In the illustrated embodiment, the power tool 10 includes an input device in the form of a rotary actuator or dial 32. This input device may be used to adjust an operational characteristic of the power tool 10 (e.g., motor torque, motor speed, etc.). In the embodiment shown, the dial 32 is located at least partially within a chin portion 30 of the power tool 10, defined between the front housing portion and the trigger 28. However, the dial 32 may be situated differently in or on the power tool 10, as will be shown in other embodiments. The dial 32 includes one or more components that are rotatable about a rotational axis R to adjust the torque setting of the power tool 10. In the illustrated embodiment, the rotational axis R intersects the front housing portion 22 and the trigger 28. As illustrated in FIGS. 1 and 2, the dial 32 is accessible from both lateral sides, as well as the front of the power tool 10. This allows the user to rotate the dial 32 about a rotational axis R (e.g., using the user's index finger) while grasping the grip 27 of the power tool 10 with the same hand, thus facilitating one-handed, ambidextrous operation of the power tool 10. The power tool 10 further includes a mode select button 15 and a forward/reverse selector 16. Although the power tool 10 illustrated in FIG. 1 is an impact driver, the power tool 10 can also be a different type of tool, such as, for example, a hammer drill, an impact hole saw, an impact driver, and the like.

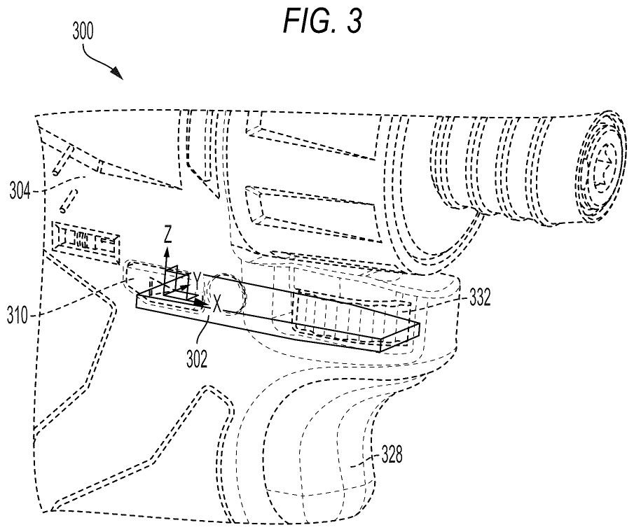

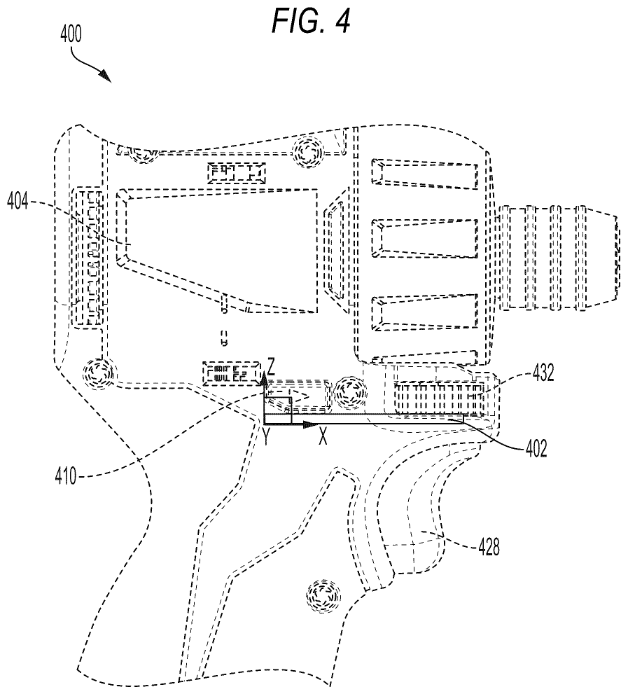

FIGS. 3 and 4 illustrate a power tool 300, 400 (e.g., power tool 10) including a circuit board 302, 402. The circuit board 302, 402 is disposed in a housing 304, 404 of the power tool 300, 400. The circuit board 302, 402 is disposed above a trigger 328, 428 of the power tool 300, 400 and below a dial 332, 432 and a sliding multi-position switch 310, 410 (sometimes referred to as a “shuttle”) of the power tool 300, 400.

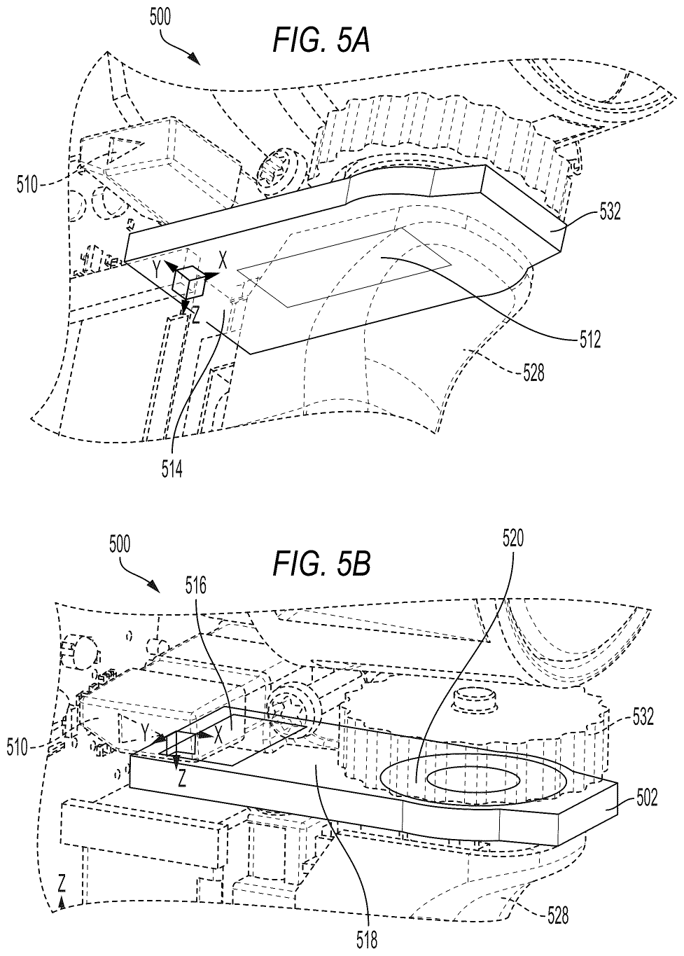

FIGS. 5A and 5B illustrate a power tool 500 (e.g., power tool 10) including a circuit board 502 having three sensing portions. A trigger sensing portion 512 is disposed on a first or bottom 514 of the circuit board 502. In the embodiment shown, the trigger sensing portion 512 is configured to sense a position of the trigger 528 along the trigger sensing portion 512. For example, the trigger sensing portion 512 may sense a trigger depression amount (e.g., not depressed, fully depressed, 75% depressed, etc.) by sensing a position target portion of the trigger 528 (e.g., a metal target portion, a spring, etc.). A multi-position switch sensing portion 516 is disposed on a second or top 518 of the circuit board 502. In the embodiment shown, the multi-position switch sensing portion 516 is configured to sense a position of the multi-position switch 510 along the multi-position switch sensing portion 516. For example, the multi-position switch sensing portion 516 may sense a plurality of discrete positions of the switch (e.g., first position, second position, third position, etc.) by sensing the position of a target portion of the multi-position switch 510 (e.g., a metal target portion of the multi-position switch 510, etc.). A dial sensing portion 520 is disposed on the top 518 of the circuit board 502. In the embodiment shown, the dial sensing portion 520 is configured to sense a position of the dial 532 along the dial sensing portion 520. For example, the dial sensing portion 520 may be ring shaped and sense a part of the dial relative to a center of the ring (e.g., 0 degrees, 45 degrees, 90 degrees, 135 degrees, 180 degrees, etc.) by sensing a position of a target portion of the dial 532 (e.g., a metal target portion of the dial 532). The sensed amounts described above may be associated with a sensed analog signal (e.g., a sensed voltage, a sensed current), or a digital representation of such a value.

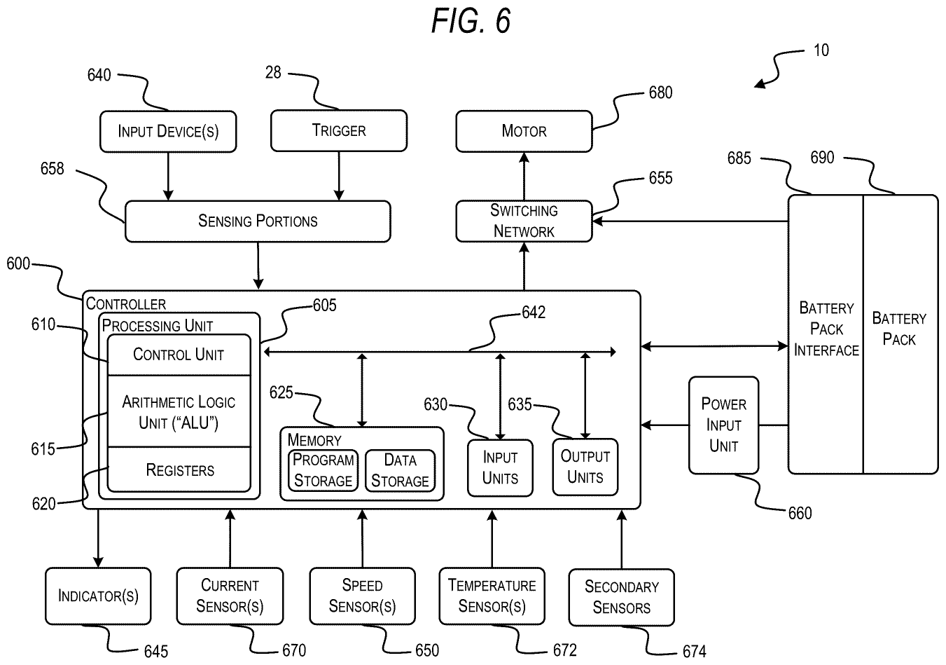

A controller 600 for the power tool 10 is illustrated in FIG. 6. The controller 600 is electrically and/or communicatively connected to a variety of modules or components of the power tool 10. For example, the illustrated controller 600 is connected to indicators 645, a current sensor 670, a speed sensor 650, a temperature sensor 672, secondary sensor(s) 674 (e.g., a voltage sensor, an accelerometer, a torque sensor or torque transducer, etc.), the trigger 28, a power switching network 655, and a power input unit 660.

The controller 600 includes a plurality of electrical and electronic components that provide power, operational control, and protection to the components and modules within the controller 600 and/or power tool 10. For example, the controller 600 includes, among other things, a processing unit 605 (e.g., a microprocessor, an electronic processor, an electronic controller, a microcontroller, or another suitable programmable device), a memory 625, input units 630, and output units 635. The processing unit 605 includes, among other things, a control unit 610, an arithmetic logic unit (“ALU”) 615, and a plurality of registers 620 (shown as a group of registers in FIG. 6), and is implemented using a known computer architecture (e.g., a modified Harvard architecture, a von Neumann architecture, etc.). The processing unit 605, the memory 625, the input units 630, and the output units 635, as well as the various modules connected to the controller 600 are connected by one or more control and/or data buses (e.g., common bus 642). The control and/or data buses are shown generally in FIG. 6 for illustrative purposes. The use of one or more control and/or data buses for the interconnection between and communication among the various modules and components would be known to a person skilled in the art in view of the embodiments described herein.

The memory 625 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 605 is connected to the memory 625 and executes software instructions that are capable of being stored in a RAM of the memory 625 (e.g., during execution), a ROM of the memory 625 (e.g., on a generally permanent basis), or another non-transitory computer readable medium such as another memory or a disc. Software included in the implementation of the power tool 10 can be stored in the memory 625 of the controller 600. The software includes, for example, firmware, one or more applications, program data, filters, rules, one or more program modules, and other executable instructions. The controller 600 is configured to retrieve from the memory 625 and execute, among other things, instructions related to the control processes and methods described herein. In other embodiments, the controller 600 includes additional, fewer, or different components.

The controller 600 drives the motor 680 to rotate a driver in response to a user's actuation of the trigger 28. The driver may be coupled to the motor 680 via an output shaft. Depression of the trigger 28 actuates a trigger switch, which outputs a signal to the controller 600 to drive the motor 680, and therefore the driver. In some embodiments, the controller 600 controls the power switching network 655 (e.g., a FET switching bridge) to drive the motor 680. For example, the power switching network 655 may include a plurality of high side switching elements (e.g., FETs) and a plurality of low side switching elements. The controller 600 may control each FET of the plurality of high side switching elements and the plurality of low side switching elements to drive each phase of the motor 680. For example, the power switching network 655 may be controlled to more quickly deaccelerate the motor 680. In some embodiments, the controller 600 monitors a rotation of the motor 680 (e.g., a rotational rate of the motor 680, a velocity of the motor 680, a position of the motor 680, and the like) via the speed sensors 650. The motor 680 may be configured to drive a gearbox (e.g., a mechanism).

The indicators 645 are also connected to the controller 600 and receive control signals from the controller 600 to turn on and off or otherwise convey information based on different states of the power tool 10. The indicators 645 include, for example, one or more light-emitting diodes (LEDs), or a display screen. The indicators 645 can be configured to display conditions of, or information associated with, the power tool 10. For example, the indicators 645 can display information relating to an operational state of the power tool 10, such as a mode or speed setting. The indicators 645 may also display information relating to a fault condition, or other abnormality of the power tool 10. In addition to or in place of visual indicators, the indicators 645 may also include a speaker or a tactile feedback mechanism to convey information to a user through audible or tactile outputs. In some embodiments, the indicators 645 display information related to a braking operation or a clutch operation (e.g., an electronic clutch operation) of the controller 600. For example, one or more LEDs are activated when the controller 600 is performing a clutch operation.

A battery pack interface 685 is connected to the controller 600 and is configured to couple with a battery pack 690. The battery pack interface 685 includes a combination of mechanical (e.g., a battery pack receiving portion) and electrical components configured to and operable for interfacing (e.g., mechanically, electrically, and communicatively connecting) the power tool 10 with the battery pack 690. The battery pack interface 685 is coupled to the power input unit 660. The battery pack interface 685 transmits the power received from the battery pack 690 to the power input unit 660. The power input unit 660 includes active and/or passive components (e.g., voltage step-down controllers, voltage converters, rectifiers, filters, etc.) to regulate or control the power received through the battery pack interface 685 and to the controller 600. In some embodiments, the battery pack interface 685 is also coupled to the power switching network 655. The operation of the power switching network 655, as controlled by the controller 600, determines how power is supplied to the motor 680.

The current sensor 670 senses a current provided by the battery pack 690, a current associated with the motor 680, or a combination thereof. In some embodiments, the current sensor 670 senses at least one of the phase currents of the motor. The current sensor 670 may be, for example, an inline phase current sensor, a pulse-width-modulation-center-sampled inverter bus current sensor, or the like. The speed sensor 650 senses a speed of the motor 680. The speed sensor 650 may include, for example, one or more Hall effect sensors. In some embodiments, the temperature sensor 672 senses a temperature of the switching network 655, the battery pack 690, the motor, or a combination thereof. The input device 640 is operably coupled to the controller 600 to, for example, select a forward mode of operation, a reverse mode of operation, a torque setting for the power tool 10, and/or a speed setting for the power tool 10 (e.g., using torque and/or speed switches), etc. In some embodiments, the input device 640 includes a combination of digital and analog input or output devices required to achieve a desired level of operation for the power tool 10, such as one or more knobs, one or more dials, one or more switches, one or more buttons, etc. In other embodiments, the input device 640 is configured as a ring (e.g., torque ring), a dial 32, a knob, a multi-position switch, etc. In some embodiments, the input device 640 interfaces with a circuit board (e.g., circuit board 502) via sensing portions 658 (e.g., trigger sensing portion 512, multi-position switch sensing portion 516, and dial sensing portion 520) configured to sense changes to a combination of input devices 640 and the trigger 28. In the embodiment shown, control of the input devices 640 sets a desired operational characteristic the motor 680 (e.g., speed of the motor 680, torque of the motor 680, motor rotational direction, etc.).

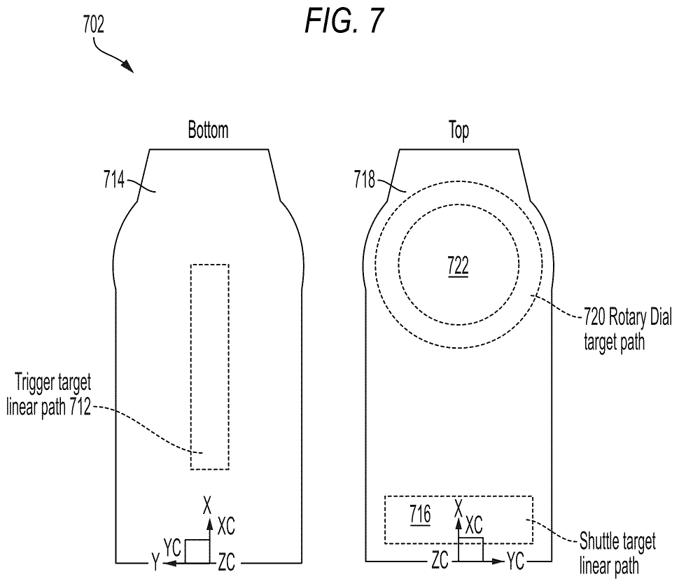

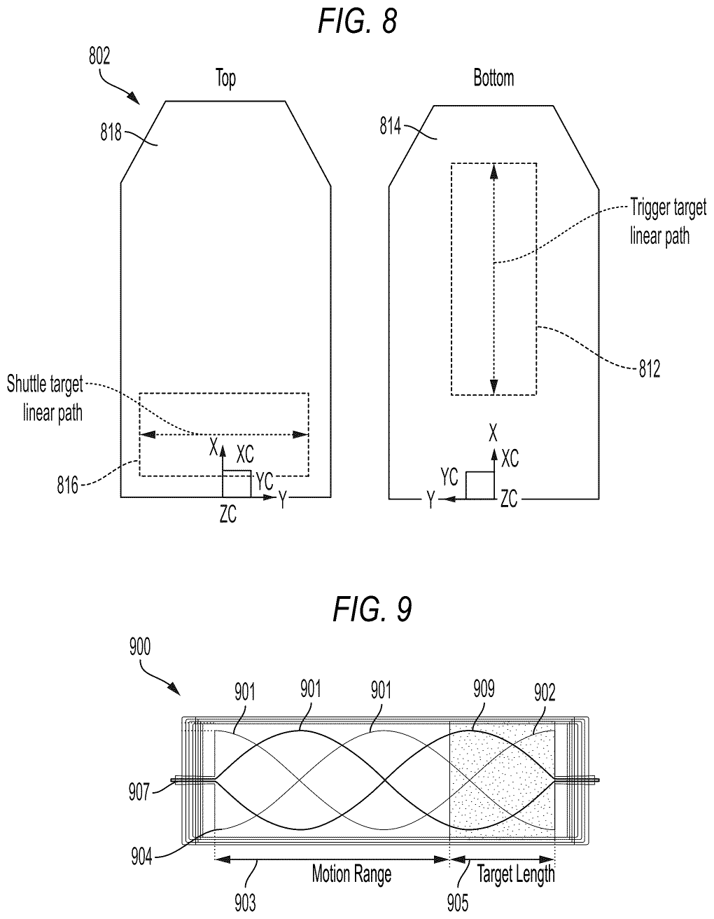

FIG. 7 illustrates a top and bottom view of a circuit board 702. The circuit board 702 includes a trigger sensing portion 712 disposed on a first side or bottom 714 of the circuit board 702. The trigger sensing portion 712 is generally rectangular in shape and its length provides a generally linear path for a target portion of a trigger 528 of a power tool 10 to travel along as the trigger 528 is depressed (e.g., by a user). A multi-position switch sensing portion 716, disposed on a second side or top 718 of the circuit board 702 is generally rectangular in shape and its width provides a generally linear path for a target portion of a multi-position switch 510 of a power tool 500 to travel along as the position of the multi-position switch 510 is changed (e.g., by a user). In the embodiment shown, multi-position switch sensing portion 716 is oriented perpendicularly to the trigger sensing portion 712. A dial sensing portion 720, disposed on the top 718 of the circuit board 702, is generally circular in shape and its circumference provides a generally circular path for a target portion of a dial 532 of a power tool 500 to travel along as the dial 532 is rotated (e.g., by a user). In the embodiment shown, the dial sensing portion 720 is ring shaped and encloses a circular portion 722 that is not part of the dial sensing portion 720. In FIG. 7, the dial sensing portion 720 is disposed a distance from the multi-position switch sensing portion 716, but may be positioned close to the multi-position switch sensing portion 716. In some embodiments, the sensing portions 658 are spaced from one another or shielded from one another (e.g., electromagnetically shielded) to prevent any of the sensing portions 658 from picking up noise or signal interference from any of the other sensing portions 658. Although much of the description of circuit boards having sensing portions 658 herein point out three distinct sensing portions 658, circuit board layouts are also contemplated that include greater or fewer than three sensing portions 658. For example, FIG. 8 shows a circuit board 802 including two sensing portions 658. Specifically, FIG. 8 shows a circuit board 802 including only a trigger sensing portion 812 on a first side or bottom 814 of the circuit board 802, and a multi-position switch sensing portion 816 on a second side or top 818 of the circuit board 802.

FIG. 9 illustrates a sensor 900 in the form of an inductive sensor 901 (e.g., including interweaved sinusoidal inductive traces). The sensor shown in FIG. 9 may be used in one of the sensing portions 658 described herein (e.g., trigger sensing portion 712, multi-position switch sensing portion 716, or dial sensing portion 720). In the embodiment shown, the sensor 900 is configured to sense a voltage as a target portion of an input device 640 (e.g., multi-position switch 510 or dial 532) or of the trigger 28 is moved along the length of the sensor (e.g., along the motion range 903). A target length 905 of the target portion of the input devices 640 and trigger 28 may be predetermined so that voltages sensed in response to the movement of the target portion over, for example, interweaved sinusoidal inductive traces of the inductive sensor 901, are predictable. As will be described in greater detail below, when a current signal is injected on the transmitting inductive trace 909, a voltage curve of receiving sinusoidal inductive traces 902, 904 may be produced and used to determine the position of target portions of the trigger 28 and input devices 640 as a target portion of an input device 640 is moved along the inductive sensor 901. The positions of the target portions may be used to determine the positions of the input devices 640 and the trigger 28. As shown in FIG. 9, the sensor 900 may include a lead 907 configured to carry the sensed voltage to another component of the power tool 400 (e.g., controller 600) for further processing.

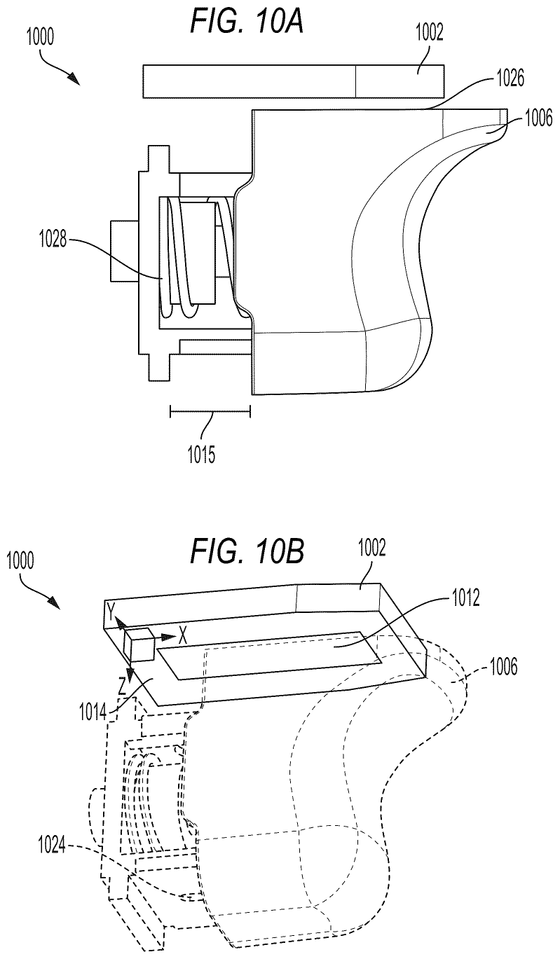

FIGS. 10A and 10B show a circuit board 1002 and a non-pivoting linear pull trigger 1006 of a power tool 1000 (e.g., power tool 10). The trigger 1006 is disposed adjacent to a first side or bottom 1014 of the circuit board 1002 and is configured to be depressed by a user so that the trigger 1006 travels a lateral distance 1015 (e.g., motion range 903) along a track 1024 such that a target portion 1026 of the trigger slides along a path near the trigger sensing portion 1012. A trigger return spring 1028 is configured to return the trigger 1006 along track 1024 to an undepressed position when the trigger 1006 is not being depressed. Although a non-pivoting trigger is shown, embodiments including pivoting triggers are contemplated.

The sensing portions 658 described herein may include an inductive sensor 900, other inductive sensors, or may include some other sensing device. For example, although it is not shown in the figures, the sensing portions 658 may include a potentiometer configured to reduce or increase an associated voltage as an associated input device 640 or trigger 28 is manipulated by a user. Additionally, the sensing portions 658 may include any number of electronic sensors such as capacitive sensors, Hall Effect sensors, photosensors, pressure sensors, etc. Various embodiments of the trigger sensing portion 712 and dial sensing portion 720 are described below. However, it is contemplated that any embodiments of sensing portions 658 described herein may be adapted for use also in each of the sensing portions 658.

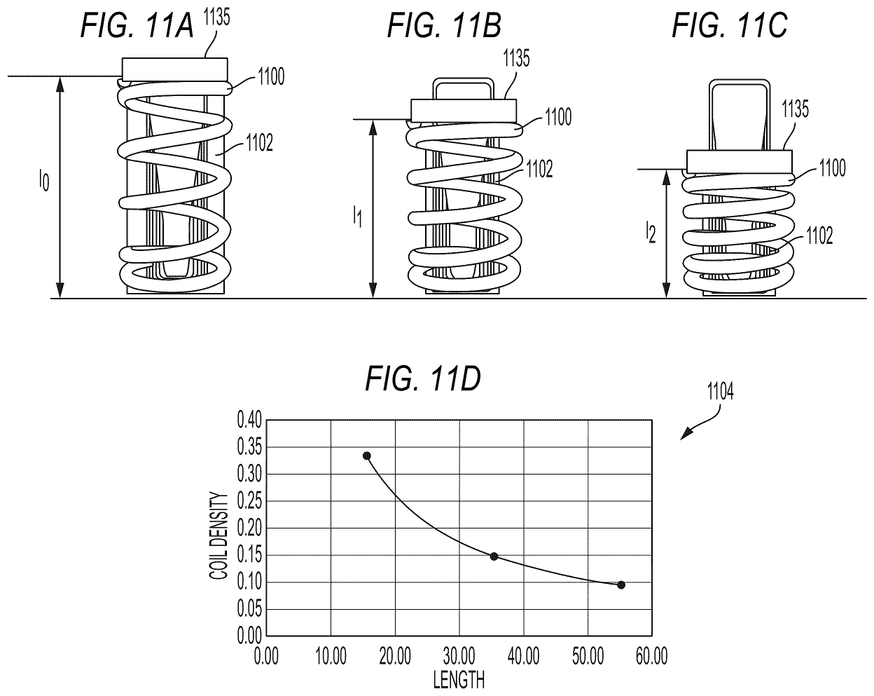

FIGS. 11A, 11B, and 11C illustrate a spring 1100, a metal target 1135, and a sensor 1102 configured to determine the position the metal target 1135. The spring 1100 is shown in isolation (i.e., not assembled with trigger 28) for illustrative purposes. In the illustrated embodiment, the sensor 1102 is a stretch inductive sensor. The sensor 1102 is approximately the same length as the spring 1100 in an uncompressed state. When the sensor 1102 is in proximity to the metal target 1135, the sensor 1102 outputs a signal related to the extent to which the spring 1100 has traveled the length of the sensor 1102. For example, the sensor 1102 may output a signal indicating that the metal target 1135 has traveled half of the length of the sensor 1102 due to a compression of the spring 1100. As illustrated in FIG. 11A, the metal target 1135 is disposed at a first end of sensor 1102 and outputs a first output signal corresponding to a current, I₀. As the spring 1100 begins to be compressed, the metal target 1135 drops below the first end of the sensor 1102. As a result, a second output signal corresponding to a current, I₁, is produced by the sensor 1102. In FIG. 11C, the spring 1100 is approximately fully-compressed and the metal target 1135 is drops toward a halfway mark along the length of the sensor 1102. In FIG. 11C, the sensor 1102 produces a third output signal corresponding to a current, I₂. The values for the first, second, and third output signals I₀, I₁, and I₂ are affected by the position of the metal target 1135. Although only three positions are shown, it is contemplated that a myriad of positions of the metal target 1135 along the length of the sensor 1102 could each be associated with a unique sensor signal.

Additionally, it is contemplated that the density of the spring 1100 may be used to produce a sensor signal indicating a position of the trigger 28. For example, as illustrated in FIG. 11D, there is a known relationship 1104 between coil density and the compressed length of the spring 1100. The relationship 1104 illustrated in FIG. 11D can be used by the controller 600 to associate the output signals from the sensor 1102 to a length of the spring 1100. When the controller 600 knows the length of the spring 1100, the controller can determine an amount of compression of the spring 1100. By monitoring the compression of the spring 1100, the controller 600 can then determine, the position of an associated input device 640 (e.g., multi-position switch 16 or dial 32) or trigger 28. As a result, the controller 600 can control an operational characteristic of the motor 680 based on the position of the trigger 28.

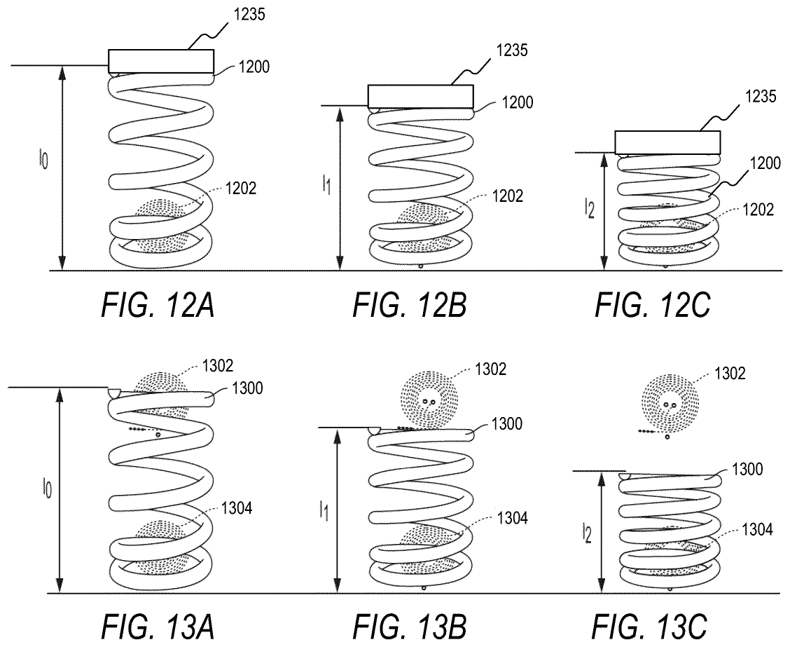

In FIGS. 12A, 12B, and 12C, the position of a metal target 1235 is detected by an inductive coil sensor 1202. The sensor 1202 is positioned near the base of the spring 1200 to detect the changes in the position of metal target 1235. Similar to the sensor 1102, the sensor 1202 generates output signals based on the position of the metal target 1235. As the spring 1200 is compressed and the position of the metal target changes, the output signals generated by the sensor 1202 vary. For example, when the metal target 1235 is in the position shown in FIG. 12A, the sensor 1202 generates a first output signal, I₀. When the metal target 1235 is in the position shown in FIG. 12B, the sensor 1202 generates a second output signal, I₁, and when the metal target 1235 is in the position shown in FIG. 12C, the sensor 1202 outputs a third signal, I₂. As a result, the controller 600 can control an operational characteristic of the motor 680 based on the position of the trigger 28. The sensor 1202 can be used with any of the sensing portions 658.

FIGS. 13A, 13B, and 13C illustrate an alternative embodiment to the spring and sensor implementation of FIGS. 12A, 12B, and 12C. In FIGS. 13A, 13B, and 13C, a spring 1300 has its compressed detected by a first sensor 1302 and a second sensor 1304. The sensor 1304 outputs signals that are substantially similar to the output signals from the sensor 1202 described above with respect to FIGS. 12A, 12B, and 12C. The sensor 1302 generates an output signal that differs from the signal generated by the sensor 1304. The output signals generated by the sensors 1302 and 1304 can be used in combination by the controller 600 to determine, for example, when the spring 1300 is fully-compressed or fully-uncompressed. As with, for example, the sensor 1202 of FIGS. 12A, 12B, and 12C, the output signals from the sensors 1302, 1304 are correlated by the controller 600 to a length of the spring 1300. When the controller 600 knows the length of the spring 1300, the controller 600 can determine the position of an associated input device 640 or trigger 28. As a result, the controller 600 can control an operational characteristic of the motor 680 based on the position of the trigger 28. The sensors 1302, 1304 can be used with any of the sensing portions 658.

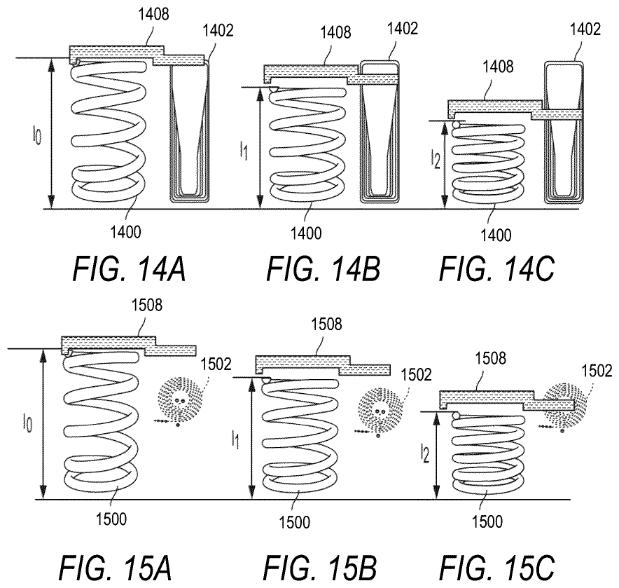

FIGS. 14A, 14B, and 14C illustrate a spring 1400 and a sensor 1402. The embodiment of FIGS. 14A, 14B, and 14C, differs from the embodiment of, for example, FIGS. 11A, 11B, and 11C in that the spring 1400 has attached to it a conductor 1408. The conductor 1408 extends away from the spring 1400 such that it partially covers a portion of the sensor 1402. The sensor 1402 is a stretch inductive sensor. Depending upon where the conductor 1408 covers the sensor 1402, an output signal generated by the sensor 1402 will vary. The output signals generated by the sensor 1402 corresponding to the conductor 1408 covering different portions of the sensor 1402 can be stored in the memory 625 of the controller 600. The controller 600 can then interpret the output signals from the sensor 1402 to determine a compression of the spring 1400 and a length of the spring 1400. When the controller 600 knows the length of the spring 1400, the controller 600 can determine position of an associated input device 640 or trigger 28. As a result, the controller 600 can control an operational characteristic of the motor 680 based on the position of the trigger 28. The sensor 1402 can be used with any of the sensing portions 658.

FIGS. 15A, 15B, and 15C illustrate a spring 1500 and a sensor 1502. The spring 1500 has attached to it a conductor 1508. The conductor 1508 extends away from the spring 1500 such that it may partially cover a portion of the sensor 1502. The sensor 1502 is a coil inductive sensor. Depending upon where the conductor 1508 is in proximity to the sensor 1502, an output signal generated by the sensor 1502 will vary. The output signals generated by the sensor 1502 corresponding to the conductor 1508 being in proximity to different portions of the sensor 1502 can be stored in the memory 625 of the controller 600. The controller 600 can then interpret the output signals from the sensor 1502 to determine a compression of the spring 1500 and a length of the spring 1500. When the controller 600 knows the length of the spring 1500, the controller 600 can determine the position of an associated input device 640 or trigger 28. As a result, the controller 600 can ensure that an operational characteristic of the motor 680 is controlled based on the position of the trigger 28. The sensor 1502 can be used with any of the sensing portions 658.

In some embodiments, in addition to affecting control of the motor 680, the trigger 28 may be configured to act as a wake source (e.g., a power-on initiator) for the power tool 10 (e.g., for controller 600). Additionally, in addition to detecting the compression of a spring 1100, 1200, 1300, 1400, 1500, the one or more sensors 1502 can also be used to detect the movement of other components commonly found within power tools. For example, a target portion of multi-position switch 510 may be shifted along the length of one of the sensors described above (e.g., sensing portion 658) and current may be induced in the sensor by the target portion (not shown) of the multi-position switch 510 passing over a particular portion of the sensor 1502, an output signal from the sensor may then vary depending upon the position of the multi-position switch 510.

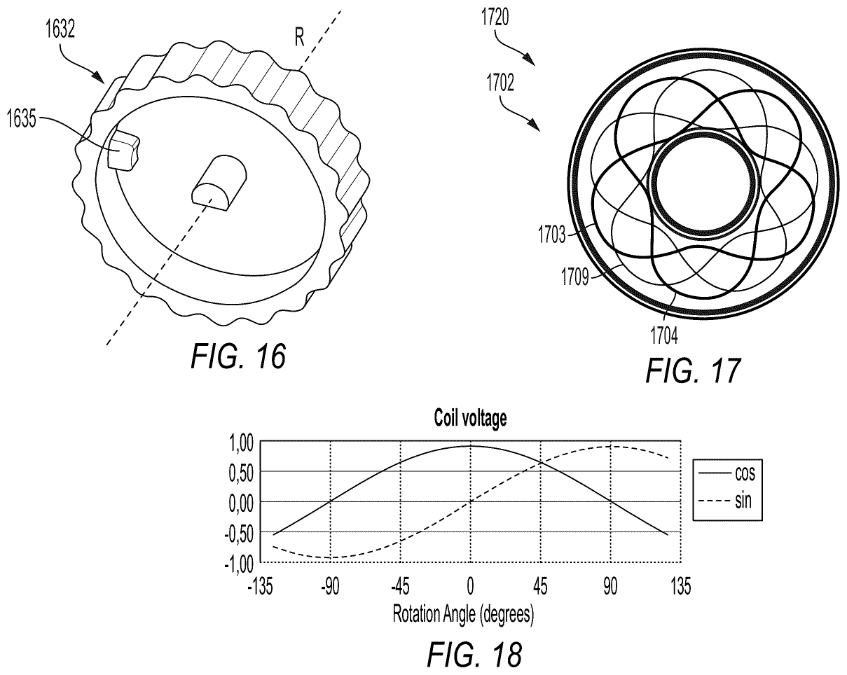

FIG. 16 shows a dial 1632 (e.g., dial 32) according to various embodiments. The dial 1632 is configured to rotate about the rotational axis R. The dial includes a target portion 1635. In the embodiment shown, the target portion 1635 is metal and configured to have an eddy current induced therein by an electromagnetic field produced by an inductive sensor (e.g., a transmitting inductive trace of an inductive sensor). In this way, the rotation of the dial 1632 can be detected by a sensor and monitored by the controller 600 as the dial 1632 rotates.

FIG. 17 illustrates an embodiment of an inductive sensor 1702 including a dial sensing portion 1720. The dial sensing portion 1720 may be included on a printed circuit board (PCB) (e.g., printed circuit board 1002) along with a transmitting circuit trace 1709, a first receiving circuit trace 1703, and a second receiving circuit trace 1704. The inductive sensor 1702 injects a current into the transmitting circuit trace 1709 to generate a magnetic field. As seen in FIG. 16, the dial 1632 includes the metal target portion 1635. As the dial 1632 rotates, the metal target portion 1635 passes through the magnetic field generated by the injection of the signal into the transmitting circuit trace 1709. Eddy currents are generated in the metal target portion 1635 of the dial 1632. The eddy currents generate a magnetic field that passes across the receiving inductive traces 1703, 1704. Current induced in the receiving inductive traces 1703, 1704 is used by the inductive sensor 1702 to determine the position of the metal target portion 1635 with respect to the receiving inductive traces 1703, 1704, and an output signal from the sensor 1702 varies depending upon an amount of rotation of the dial 1632. Accordingly, the controller 600 is able to correlate a value of an output signal from the sensor 1702 to an amount of rotation of the dial 1632.

In some embodiments, the receiving inductive circuit traces 1703, 1704 are sinusoidal in shape but offset by 90°, so that as the target portion 1635 passes over the receiving inductive traces 1703, 1704, the voltage in one of the receiving inductive traces 1703 is a sine wave and the voltage in the other receiving inductive trace 1704 is a cosine wave. The voltage output (example shown in FIG. 18) of the two inductive traces 1703, 1704 can then be used by the controller 600 to determine the position (e.g., rotational angle) of the dial 1632 with respect to the receiving inductive traces 1703, 1704. In some embodiments, the angle is generated by the controller 600 using an arctangent function,

$$a = arctan \frac{{v}_{sin}}{{v}_{cos}} .$$

In some embodiments, the sensor 1702 achieves a resolution of approximately 0.15° for detection of the position of the target portion 1635 of the dial 1632 and has a detection accuracy of greater than 98%.

In some alternative embodiments, a potentiometer is used in conjunction with the dial 1632. As the dial 1632 rotates, it rotates and associated potentiometer (not shown). The potentiometer sends electronic signals to the controller 600 to adjust an operational characteristic of the motor 680 of the power tool 10. The circuit board 1002 may remain stationary as the dial 1632 rotates. In some embodiments, there may be a block which will not allow the dial 1632 to freely revolve about the rotational axis R. In other embodiments, there is not a block, meaning the dial 1632 is allowed to freely revolve about the rotational axis R.

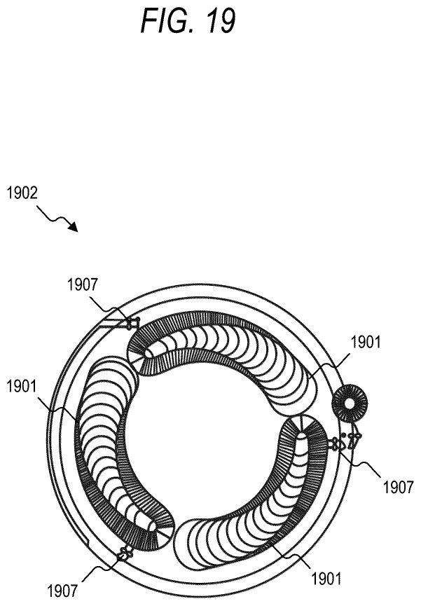

FIG. 19 shows an alternative arrangement for an inductive sensor embodiment of the dial sensing portion 1720. In the embodiment shown, an inductive sensor 1902 is ring shaped and includes strategically spaced inductive traces 1901 arranged such that current induced in the inductive traces 1901 and communicated to a controller 600 via leads 1907 can be identified by the controller 600 as indicating a current position of the target portion 1635.

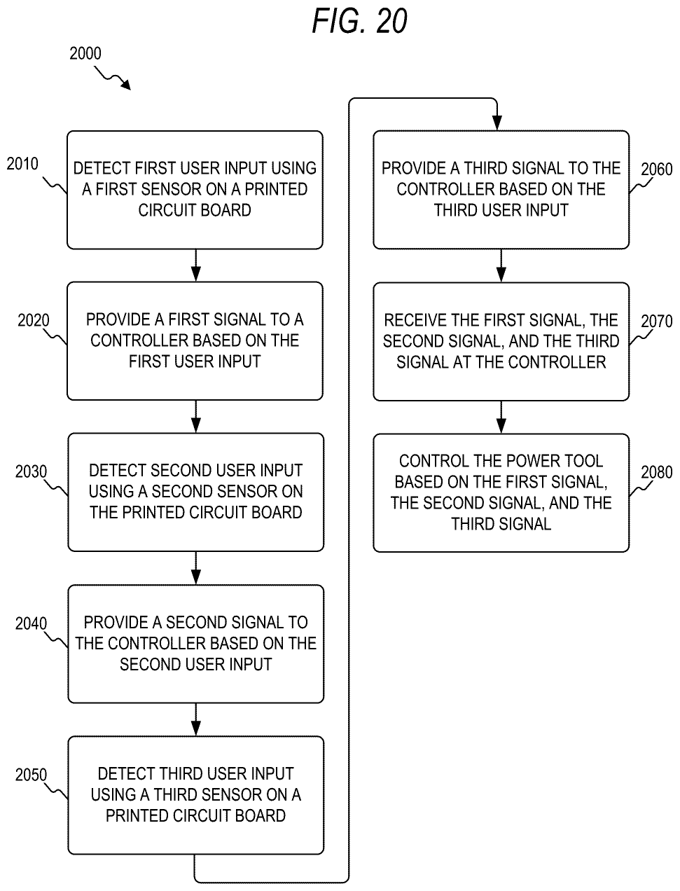

FIG. 20 is a flow chart 2000 for a method of receiving signals sensors from on the circuit board 1002 and controlling an operational characteristic of a power tool 10 based on the sensor signals.

At block 2010, a first sensor (e.g., trigger sensing portion 512) on a circuit board 1002 of a power tool 10 detects a first user input (e.g., a depression of trigger 528).

At block 2020, the first sensor provides a first sensor signal to the controller 600 based on the first user input.

At block 2030, a second sensor (e.g., multi-position switch sensing portion 516) on the circuit board 1002 of a power tool 10 detects a second user input (e.g., a change of position of multi-position switch 510).

At block 2040, the second sensor provides a second sensor signal to the controller 600 based on the second user input.

At block 2050, a third sensor (e.g., dial sensing portion 520) on the circuit board 1002 of a power tool 10 detects a second user input (e.g., a rotation of dial 532).

At block 2060, the third sensor provides a third sensor signal to the controller 600 based on the third user input.

At block 2070, the controller 600 receives the first, second, and third sensor signals from the first, second, and third sensors.

At block 2080, the controller 600 controls an operational characteristic of a motor 680 of the power tool 10, based on the first, second, and third sensor signals.

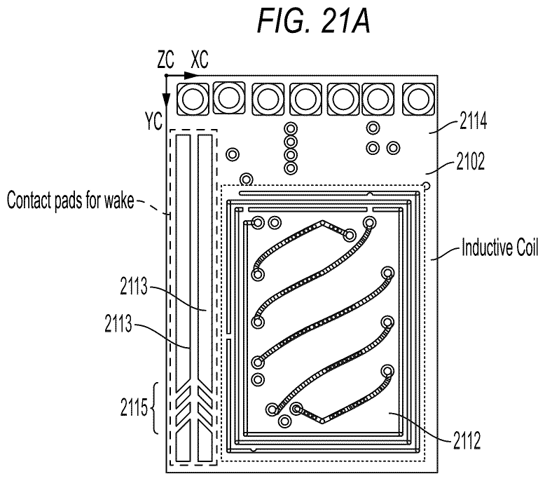

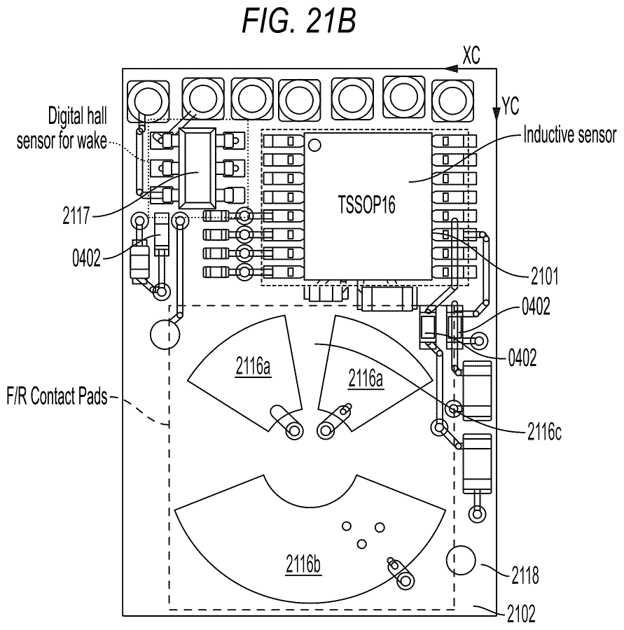

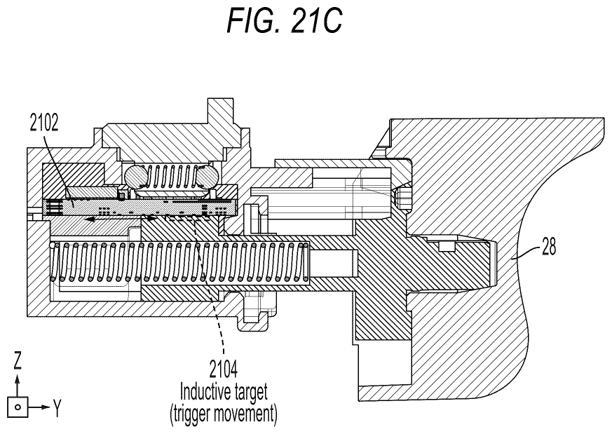

FIGS. 21A, 21B, and 21C illustrate a circuit board 2102 for the power tool 10. The circuit board 2102 includes a plurality of sensing portions and sensing components. FIG. 21A shows a bottom 2114 of the circuit board 2102. The bottom 2114 of the circuit board 2102 includes a first sensor, such as an inductive coil 2112, and a second sensor, such as wiper contact pads 2113. FIG. 21B shows a top 2118 of the circuit board 2102. The top 2118 of the circuit board 2102 includes a third sensor, such as forward/reverse contact pads 2116a, 2116b. The circuit board 2102 can also include an inductive sensor 2101 connected to the inductive coil 2112 and a magnetic sensor 2117 (e.g., a digital Hall Effect sensor).

During use of the power tool 10, a target portion 2104 (e.g., a metal target portion or magnet) of a first user input (e.g., the trigger 28 of the power tool 10) may be configured to move forward and backward with respect to the inductive coil 2112 as the trigger 28 is depressed and released. The inductive sensor 2101 is configured to inject a current signal into the inductive coil 2112, and an electromagnetic field may be induced in the target portion 2104 of the trigger 28. The electromagnetic field induced in the target portion 2104 of the trigger 28 may in turn influence a current conducted through the inductive coil 2112. The inductive sensor 2101 is configured to detect changes in current conducted by the inductive coil 2112 and to determine a position of the trigger 28 based on detected changes in current.

In some embodiments, the trigger 28 of the power tool 10 is mechanically connected a contact wiper or arm such that the contact wiper moves along wiper contact pads 2113 as the trigger 28 of the power tool is depressed. The wiper contact pads 2113 include a ribbed portion 2115 such that a wake signal is generated when the contact wiper moves across the wake portion 2115 and onto the wiper contact pads 2113. As will be described in further detail below, under certain circumstances, a wake signal may be transmitted to the controller 600 as a result of certain manipulations of the power tool 10 (e.g., a depression of the trigger 28, a manipulation of a switch, dial, or selector, etc.).

Forward/reverse contact pads 2116a, 2116b on the top 2118 of the circuit board 2102 are configured to detect a manipulation of a second user input (e.g., a forward/reverse selector, multi-position switch 510, etc.). In the embodiment shown, a first contact of the forward/reverse selector is configured to remain in contact with the rear contact pad 2116b while a second contact of the forward/reverse selector is configured to be shifted (e.g., by user manipulation of a button or dial) between the forward contact pads 2116a as needed to select a forward or reverse operating mode of the power tool 10. A non-contact space 2116c is disposed between the front contact pads 2116a and may be configured to accommodate a front contact of the forward/reverse selector when neither the forward operating mode nor the reverse operating mode of the power tool 10 are selected. In some embodiments, moving the front contact of the forward/reverse selector (e.g., by user manipulation of a button or dial) between the front contact pads 2116a or from one of the front contact pads 2116a to the no-contact space 2116c generates a wake signal that is transmitted to the controller 600.

In some embodiments, a dial sensing portion (e.g., dial sensing portion 520) is included on the circuit board 2102 and is operable to sense the position of a dial (e.g., dial 532) as a user changes the position of the dial. The dial sensing portion 520 may be implemented using inductive traces as described with respect to FIG. 17, or may be implemented using contact pads (e.g., a plurality of contact pads corresponding to a plurality of distinct, predetermined positions of the dial) as described with respect to FIG. 21B. In such embodiments, the dial sensing portion 520 may be configured to transmit a wake signal to the controller 600 in response to a manipulation of the dial 532.

The wake signal may be a voltage signal generated by an auxiliary circuit connected to the inductive coil 2112, the wiper contact pads 2113, the forward/reverse contact pads 2116a, 2116b, or the dial sensing portion 520. In some embodiments, the inductive coil 2112, the wiper contact pads 2113, and the forward/reverse contact pads 2116a, 2116b are configured to generate the wake signal. For example, in some embodiments, a current induced in the metal target or contacts by the inductive coil 2112, the wiper contact pads 2113, or the forward/reverse contact pads 2116a, 2116b, respectively, is used as the wake signal. Additionally, in embodiments wherein the target portion 2104 is a magnet, a current induced in the inductive coil 2112 by a motion of the magnet with respect to the inductive coil 2112 may be used as the wake signal.

The magnetic sensor 2117 is configured to sense a magnetic field (e.g., generated in the target portion 2104 of the trigger 28 by the inductive coil 2112) or order to wake the controller 600. The magnetic sensor 2117 may be configured to sense a change in the intensity of the magnetic field as the target portion 2104 moves away from the magnetic sensor 2117 as the trigger 28 is depressed. In response to sensing this change in intensity of the magnetic field, the magnetic sensor 2117 may transmit a wake signal to the controller 600. In some embodiments, the magnetic sensor 2117 is not required and can be removed from the printed circuit board 2102.

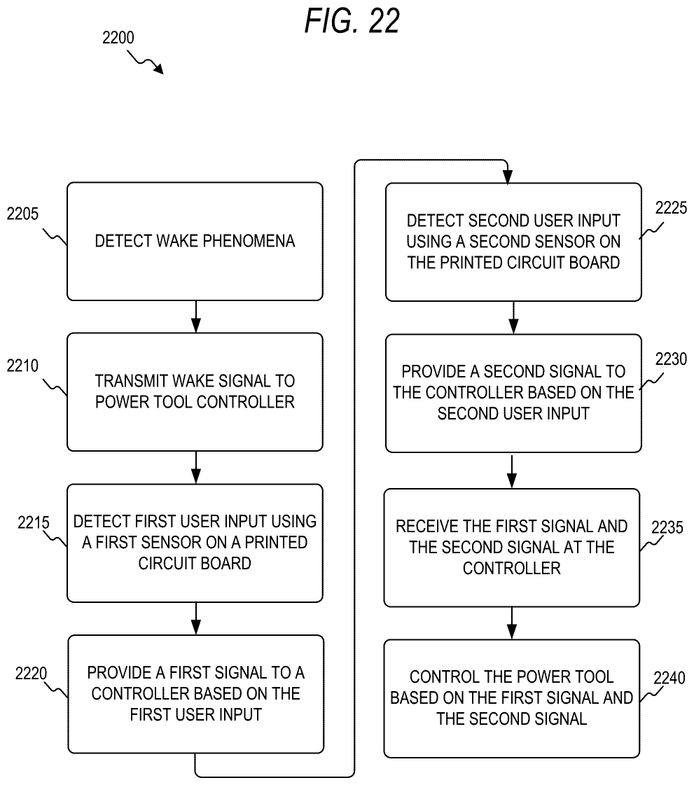

Prior to receiving the wake signal, the controller 600 may be in a sleep state (e.g., a power conservation or OFF mode). Upon receiving the wake signal, the controller 600 may wake or power on. After waking or powering on, the controller 600 may function as described with respect to FIG. 20 or FIG. 22.

FIG. 22 is a flow chart 2200 for a method of receiving one or more sensor signals from the circuit board 2102 and controlling an operational characteristic of the power tool 10 based on the one or more sensor signals.

At block 2205, a wake condition is detected. For example, the wake condition can include the wiper contact pads 2113 detecting a contact wiper or arm sliding across ribbed portion 2115 onto contact pads 2113, the magnetic sensor 2117 detecting a change in an intensity of a magnetic field in proximity to the magnetic sensor 2117 as the trigger 28 is depressed, or front contact pads 2116a detecting a front contact of a forward/reverse selector contacting front contact pads 2116a as it changes position due to user manipulation.

At block 2210, a wake signal is transmitted to the controller 600. For example, the wiper contact pads 2113, the magnetic sensor 2117, and/or forward/reverse contact pads 2116a, 2116b, send a wake signal to the controller 600 to wake up or power on the controller 600.

At block 2215, a first sensor (e.g., inductive sensor 2101) on a circuit board 2102 of the power tool 10 detects a first user input (e.g., a depression of trigger 28).

At block 2220, the first sensor provides a first sensor signal to the controller 600 based on the first user input (e.g., as a speed control input for controlling a speed of the motor 680).

At block 2225, a second sensor (e.g., forward/reverse selector) on the circuit board 2102 of a power tool 10 detects a second user input (e.g., a change of position of forward/reverse selector).

At block 2230, the second sensor provides a second sensor signal to the controller 600 based on the second user input (e.g., for controlling a forward/reverse rotational direction of the motor 680).

At block 2235, the controller 600 receives the first and second sensor signals from the first and second sensors.

At block 2240, the controller 600 controls one or more operational characteristics of the motor 680 of the power tool 10 based on the first and second sensor signals.

Thus, embodiments described herein provide, among other things, a power tool including a circuit board having multiple sensors configured to sense the positions of various input devices. Various features and advantages are set forth in the following claims.

What is claimed is:

1. A power tool comprising:
a housing;
a motor at least partially disposed within the housing;
a controller configured to control an operational characteristic of the motor; and
a circuit board connected to the controller, the circuit board including:
a first sensor configured to sense a first position of a first user input device,
a second sensor configured to sense a second position of a second user input device, and
a third sensor configured to sense a third position of a third user input device.

2. The power tool of claim 1, wherein:
the first user input device is a dial of the power tool;
the first sensor is disposed on a first side of the circuit board; and
the first position of the first user input device is a rotational position of the dial.

3. The power tool of claim 1, wherein:
the second user input device is a multi-position switch of the power tool; and
the second sensor is disposed on a first side of the circuit board;
wherein the second position of the second user input device is a lateral position of the multi-position switch.

4. The power tool of claim 3, wherein:
the third user input device is a trigger of the power tool;
the third sensor is disposed on a second side of the circuit board; and
the third position of the third user input device is a depression position of the trigger.

5. The power tool of claim 1, wherein:
the first sensor is a first inductive sensor; and
the second sensor is a second inductive sensor.

6. The power tool of claim 5, wherein the third sensor is a third inductive sensor.

7. The power tool of claim 6, wherein the first user input device includes a metal target portion configured to produce a current in the first inductive sensor when the first user input device is moved with respect to the first inductive sensor.

8. A power tool comprising:
a housing;
a motor at least partially disposed within the housing;
a controller configured to control an operational characteristic of the motor in response to receiving a wake signal; and
a circuit board connected to the controller, the circuit board including:
a first sensor configured to sense a first position of a first user input device, and
a second sensor configured to sense a second position of the first user input device.

9. The power tool of claim 8, wherein:
the first user input device is a trigger including a target portion, the target portion being a metal target; and
the first sensor is an inductive sensor.

10. The power tool of claim 9, wherein:
the metal target is sensed by an inductive coil connected to the inductive sensor; and
the second sensor is a Hall Effect sensor.

11. The power tool of claim 10, wherein the Hall Effect sensor is configured to provide the wake signal to a controller of the power tool in response to sensing that the metal target has moved away from the Hall Effect sensor or in response to sensing that the metal target or magnet has moved toward to the Hall Effect sensor.

12. The power tool of claim 11, wherein the inductive sensor is on a first side of the circuit board and the inductive coil is on a second side of the circuit board.

13. The power tool of claim 9, further comprising:
a contact wiper connected to the trigger; and
a wiper contact pad disposed on the circuit board,
wherein the wiper contact pad is configured provide the wake signal to the controller in response to the contact wiper moving across the wiper contact pad.

14. A trigger switch comprising:
a trigger including a target portion, the trigger being actuatable by a user to move the target portion from a first position to a second position; and
a printed circuit board (PCB) having a first non-contact sensor and a second non-contact sensor, the PCB disposed above the trigger such that the trigger moves between the first position and the second position along a first side of the PCB,
wherein the first non-contact sensor is configured to detect a position of the target portion as the target portion moves between the first position and the second position, and
wherein the second non-contact sensor is configured to provide a wake signal to a controller in response to the target portion being moved from the first position.

15. The trigger switch of claim 14, wherein the first non-contact sensor is an inductive sensor and the target portion is a metal target.

16. The trigger switch of claim 15, wherein the second non-contact sensor is a Hall Effect sensor.

17. The trigger switch of claim 14, wherein the first non-contact sensor and the second non-contact sensor are on a second side of the PCB.

18. The trigger switch of claim 14, wherein the first non-contact sensor is an inductive sensor connected to an inductive coil.

19. The trigger switch of claim 18, wherein the inductive sensor is on the first side of the PCB and the inductive coil is on a second side of the PCB.

20. The trigger switch of claim 14, wherein the target portion and PCB are disposed in a housing of the trigger switch.
